(19) United States
(12) Patent Application Publication
(10) Pub. No.: US 2022/0123237 A1
(43) Pub. Date: Apr. 21, 2022

(54) MULTI-LAYER COMPOSITE SUPPORTING BACKPLANE OF FLEXIBLE PANEL

(71) Applicant: Huang-Chieh Metal Composite Material Tech. Co., Ltd., New Taipei City (TW)

(72) Inventor: Chin-Han Wang, New Taipei City (TW)

(21) Appl. No.: 17/071,825

(22) Filed: Oct. 15, 2020

(51) Int. Cl. H01L 51/00; B32B 15/01

(52) U.S. Cl. CPC H01L 51/0097; B32B 15/015; B32B 2457/206; B32B 2307/732; B32B 2250/02; H01L 2251/5338

(57) ABSTRACT

An embodiment of the invention provides a supporting backplane made of a composite metallic sheet with a two-layer structure. The composite metallic sheet is made of a first metal layer and a second metal layer, which are made of different metallic materials. The first metal layer and the second metal layer are combined by a rolling process. A hardness or an elastic coefficient of the first metal layer is greater than a hardness or an elastic coefficient of the second metal layer. Another embodiment of the invention provides a composite metallic sheet with more than two layers. The first metal layer and the second metal layer are interlacedly superposed and combined by a rolling process. The advantage and function of the invention are a great service life and an adjustable elasticity of the supporting backplane after being folded or bent by adjusting the relative thickness ratio of the first metal layer and the second metal layer.

### TECHNICAL FIELD

The invention relates to flexible displays, particularly to a multi-layer composite supporting backplane attached on a back of a flexible panel for supporting the flexible panel.

### RELATED ART

Flat panel display (FPDs) have been developed from thin, light portable durable displays to bendable displays. Soft displays that are getting more and more attention can be called “flexible display” and are the focus of the future development of the displays. The flexible panel, which is a key component of flexible displays, is just the most important item of the development of the industry.

For the reading feeling provided by a display, because both tablet PCs and flat electronic book reading devices appear in the market, displays for compact electronic devices, especially for the smartphones, have reached a limit. In recent years, the breakthrough of “flexible OLED panel” technology has led to the launch of folding phones. A flexible display made of an OLED panel can be curled or folded just like paper and has advantages of large displaying and portability, so a foldable smartphone can provide a new reading experience to users. Also, a flexible display can be deformable depending on demands, for example, a panel can be shown in a curved or annular shape. In the near future, the flexible displays will further bring a different reading experience to users.

China patent No. 107564417A provides a backplane of a flexible display panel, which includes a first backplane. The first backplane includes at least two first sub-backplanes connected to each other. Two adjacent first sub-backplanes are connected with bendable bending portions. The bending portions are made of flexible and deformable material such as silicone. The bending portions may adopt bellows or hinges. However, such a backplane of a flexible display can only be applied to a foldable smartphone, but cannot applied to a curlable flexible display.

### SUMMARY OF THE INVENTION

An object of the invention is to provide a multi-layer composite supporting backplane of a flexible panel, which is used to be attached on a back of a flexible panel for supporting the flexible panel.

To accomplish the above object, the invention provides a multi-layer composite supporting backplane of a flexible panel. The supporting backplane is made of a composite metallic sheet with a total thickness T between 0.03 mm and 0.5 mm. The composite metallic sheet includes a first metal layer and a second metal layer. The first metal layer and the second metal layer are made of different metallic materials. The first metal layer and the second metal layer are combined by a rolling process. A hardness or an elastic coefficient of the first metal layer is greater than a hardness or an elastic coefficient of the second metal layer. A ratio of a thickness t1 of the first metal layer to a thickness t2 of the second metal layer is t1:t2=1˜9:1 or t1:t2=1:1˜9.

The first metal layer and the second metal layer are selected from stainless steel, carbon steel, titanium, copper, nickel, titanium copper alloy, beryllium copper or aluminum alloy.

The composite metallic sheet comprises two layers, one is the first metal layer, and another one is the second metal layer.

The composite metallic sheet comprises more than two layers, odd layers are the first metal layers, and even layer(s) is/are the second metal layer(s).

A total thickness of the composite metallic sheet is between 0.03 mm and 0.5 mm, the first metal layer is stainless steel, the second metal layer is copper, and a minimum bending radius of the composite metallic sheet is 1T˜2T.

The advantage and function of the invention are

In comparison with conventional flexible display backplanes adopting rubber, bellows or hinges, the invention does not have a complicated structure and has a great service life and an excellent elasticity of the supporting backplane after being folded or bent.

### BRIEF DESCRIPTION OF THE DRAWINGS

FIG. 1 is a cross-sectional view of an embodiment of the invention;

FIG. 2 is a cross-sectional view of another embodiment of the invention;

FIG. 3 is a schematic view of the invention under stress;

FIG. 4 is a schematic view of the invention in use;

FIG. 5 is another schematic view of the invention in use; and

FIG. 6 is a scanning electron micrograph of an embodiment of the invention.

### DETAILED DESCRIPTION OF THE INVENTION

As used herein, words such as “inner” and “outer,” “interior” and “exterior,” “upper” and “lower,” “outside” and “inside,” “top” and “bottom,” “left” and “right,” “inwardly” and “outwardly” and words of similar import are intended to assist in understanding preferred embodiments of the invention with reference to the accompanying drawing Figures and with respect to the orientation of the invention as shown in the Figures, and are not intended to be limiting to the scope of the invention or to limit the invention scope to the preferred embodiments shown in the Figures.

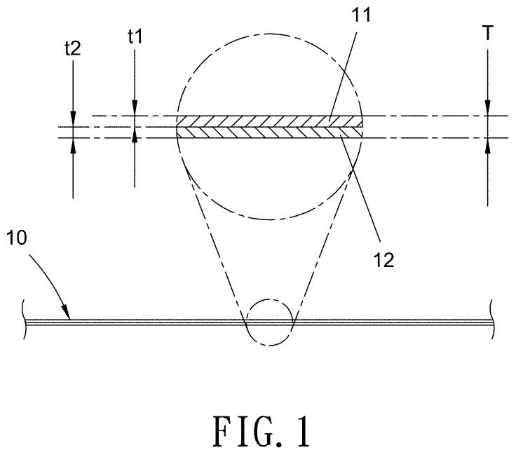

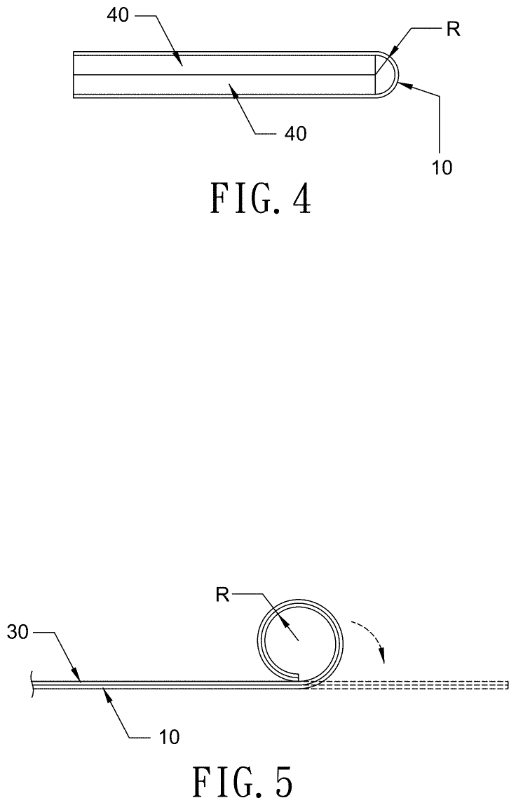

Please refer to FIG. 1, which is a cross-sectional view of an embodiment of the multi-layer composite supporting backplane of a flexible panel of the invention. The multi-layer composite supporting backplane of a flexible panel of the invention is made of a composite metallic sheet 10 with a total thickness T between 0.03 mm and 0.5 mm. The minimum bending radius R of the composite metallic sheet 10 is 1T˜2T. The composite metallic sheet 10 includes a first metal layer 11 and a second metal layer 12. The first metal layer 11 and the second metal layer 12 are made of different metallic materials which are selected from stainless steel, carbon steel, titanium, copper, nickel, titanium copper alloy, beryllium copper or aluminum alloy. The materials which are used to manufacture the first metal layer 11 and the second metal layer 12 are treated by a rolling process to form different metallic sheets and the different metallic sheets are combined by a rolling process to form the composite metallic sheet 10. A hardness or an elastic coefficient of the first metal layer 11 is greater than a hardness or an elastic coefficient of the second metal layer 12. A ratio of a thickness t1 of the first metal layer 11 to a thickness t2 of the second metal layer 12 may be adjusted depending on the hardness or the elastic coefficients of the respective metallic materials and the performance specifications of the flexible panels such as the minimum bending radius R of the flexible panel 30 (as shown in FIGS. 4 and 5). As a preferred embodiment of the invention, a ratio of a thickness t1 of the first metal layer 11 to a thickness t2 of the second metal layer 12 is 1˜9:1 or 1:1˜9, for example, t1:t2=7:3, t1:t2=3:7, t1:t2=8:2 or t1:t2=2:8, etc.

In a preferred embodiment of the multi-layer composite supporting backplane of a flexible panel of the invention, the composite metallic sheet 10 is of a two-layer structure, the one is the first metal layer 11, and the other one is the second metal layer 12.

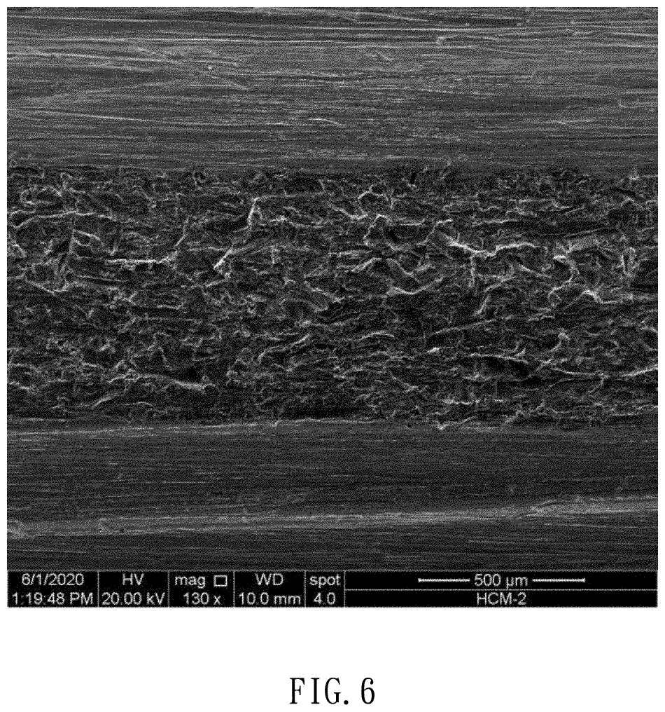

In another preferred embodiment of the multi-layer composite supporting backplane of a flexible panel of the invention, the composite metallic sheet 10 is of a three-layer structure. The second metal layer 12 serves as an intermediate layer and the first metal layer 11 serves as the outmost two layers of the composite metallic sheet 10 with the three-layer structure. A hardness or an elastic coefficient of the first metal layer 11 is greater than a hardness or an elastic coefficient of the second metal layer 12. When a better wearability is required, the composite metallic sheet 10 with the three-layer structure can enhance the surface wearability of the multi-layer composite supporting backplane of a flexible panel. Please refer to FIG. 6, which is a scanning electron micrograph of an embodiment of the invention. The composite metallic sheet 10 serving as a multi-layer composite supporting backplane of a flexible panel includes a three-layer structure, they are 201 stainless steel/6063 aluminum alloy/201 stainless steel. Such a three-layer structure is a relatively hard/soft/hard metallic composite structure. Further, a thickness ratio of the three-layer structure can be adjusted depending on requirements and then a finally required total thickness T can be obtained by a rolling process.

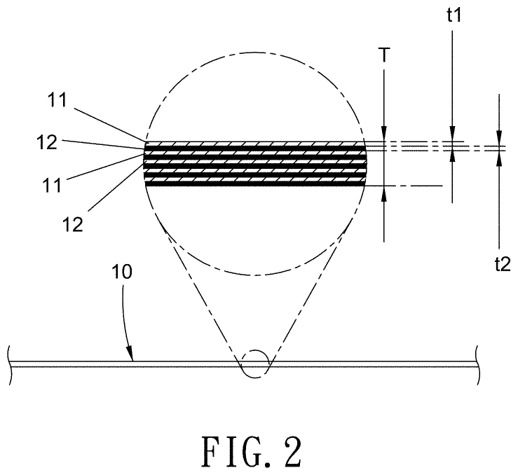

Please refer to FIG. 2, which is a cross-sectional view of another embodiment of the invention. In another preferred embodiment of the multi-layer composite supporting backplane of a flexible panel of the invention, the composite metallic sheet 10 is of a more-than-two-layer structure. The embodiment shown in FIG. 2 is the composite metallic sheet 10 with a ten-layer structure. In the more-than-two-layer structure, the odd layers are the first metal layers and the even layer(s) is/are the second metal layer(s) 12. In other words, the invention selects a soft metallic material and a hard metallic material (or a metallic material with a high elastic coefficient and a metallic material with a low elastic coefficient) to be made into metallic sheets, and then the metallic sheets are interlacedly superposed to be combined into the composite metallic sheet 10 with a ten-layer structure.

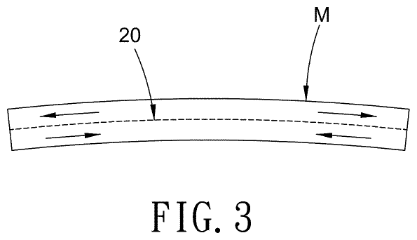

Please refer to FIG. 3, which is a schematic view of the invention under stress. According to the structural analysis of the mechanics of materials to a homogeneous material M which forms bending deformation after being subjected to bending stress, it can be realized that when bending deformation occurs in a homogeneous material M, the plane on which a longitudinal length of the homogeneous material M does not vary is called “neutral surface” 20. Symmetrical positions at two sides of the neutral surface 20 will be subjected to compressive stress and tensile stress respectively. Also, the magnitude of the compressive stress and the tensile stress at a point of a material is proportional to the vertical distance from the force position of the material to the neutral surface 20. That is, in the cross section of the homogeneous material, the farther the distance between the material and the neutral plane 20 is, the greater the compressive stress and tensile stress of the material is. Thus, varying the thickness of the homogeneous material M can minimize the furthermost distance from the neutral surface 20 on the cross section. As a result, the compressive stress and tensile stress of the material can be relatively reduced. According to this principle, the invention selects a soft metallic material and a hard metallic material (or a metallic material with a high elastic coefficient and a metallic material with a low elastic coefficient) to be made into a composite metallic sheet 10 with a multi-layer structure and a total thickness T between 0.03 mm and 0.5 mm by a rolling process. Such a composite metallic sheet is attached on a back of the flexible panel 30 to serve as the multi-layer composite supporting backplane of the flexible panel 30.

In a preferred embodiment of the multi-layer composite supporting backplane of a flexible panel of the invention, the total thickness T of the composite metallic sheet 10 is 0.5 mm, the first metal layer 11 is stainless steel (such as 301 stainless steel), the second metal layer 12 is copper, and a thickness ratio of the first metal layer 11 to the second metal layer 12 is 1:1. The minimum bending radius R of such a composite metallic sheet 10 can reach 1T˜2T (T stands for the total thickness of the composite metallic sheet). As shown in FIGS. 4 and 5, the composite metallic sheet 10 can be attached on a back of the flexible panel 30 for supporting the flexible panel 30. The multi-layer composite supporting backplane of a flexible panel of the invention has a great service life and an adjustable elasticity of the supporting backplane after being folded or bent by adjusting the relative thickness ratio of the first metal layer and the second metal layer so as to be applied to a flexible display 40 (as shown in FIG. 4) of a foldable smartphone or a curlable flexible panel 30 (as shown in FIG. 5).

What is claimed is:

1. A multi-layer composite supporting backplane of a flexible panel, the supporting backplane being made of a composite metallic sheet with a total thickness T between 0.03 mm and 0.5 mm, the composite metallic sheet comprising a first metal layer and a second metal layer, the first metal layer and the second metal layer being made of different metallic materials, the first metal layer and the second metal layer being combined by a rolling process, a hardness or an elastic coefficient of the first metal layer being greater than a hardness or an elastic coefficient of the second metal layer, and a ratio of a thickness t1 of the first metal layer to a thickness t2 of the second metal layer being t1:t2=1˜9:1 or t1:t2=1:1˜9.

2. The multi-layer composite supporting backplane of claim 1, wherein the first metal layer and the second metal layer are selected from stainless steel, carbon steel, titanium, copper, nickel, titanium copper alloy, beryllium copper or aluminum alloy.

3. The multi-layer composite supporting backplane of claim 1, wherein the composite metallic sheet comprises two layers, one is the first metal layer, and another one is the second metal layer.

4. The multi-layer composite supporting backplane of claim 1, wherein the composite metallic sheet comprises more than two layers, odd layers are the first metal layers, and even layer(s) is/are the second metal layer(s).

5. The multi-layer composite supporting backplane of claim 1, wherein a total thickness of the composite metallic sheet is between 0.03 mm and 0.5 mm, the first metal layer is stainless steel, the second metal layer is copper, and a minimum bending radius of the composite metallic sheet is 1T˜2T.

6. The multi-layer composite supporting backplane of claim 5, wherein the composite metallic sheet comprises two layers, one is the first metal layer, and another one is the second metal layer.

7. The multi-layer composite supporting backplane of claim 5, wherein the composite metallic sheet comprises more than two layers, odd layers are the first metal layers, and even layer(s) is/are the second metal layer(s).
